(19) United States
(12) Patent Application Publication
(10) Pub. No.: US 2013/0161457 A1
(43) Pub. Date: Jun. 27, 2013

(54) PHOTOVOLTAIC MODULE MOUNTING SYSTEM

(71) Applicant: Christopher Stephen Klinga, Boulder, CO (US)

(72) Inventor: Christopher Stephen Klinga, Boulder, CO (US)

(73) Assignee: LUMOS LSX, LLC, Boulder, CO (US)

(21) Appl. No.: 13/538,818

(22) Filed: Jun. 29, 2012

Related U.S. Application Data
(60) Provisional application No. 61/548,147, filed on Oct. 17, 2011.

(51) Int. Cl. H01L 31/042; F16M 13/02

(52) U.S. Cl. CPC H01L 31/0424; F16M 13/022
USPC 248/201; 403/109.1

(57) ABSTRACT

A photovoltaic (“PV”) module mounting system including a standoff adapted to be secured to a support surface, the standoff having an elongate channel formed along a length thereof. A rail attachment member has a portion disposed in the channel. The rail attachment member is positionably adjustable along the length of the rail. An elongate rail is securable to the standoff by the rail attachment member. The position of the rail is adjustable along the length of the standoff and fixedly secured. The elongate rail has a slot extending along a length thereof. The slot accommodates PV panel mounting hardware therein for securing a PV panel to the rail.

This application claims the benefit of priority to U.S. Provisional Patent Application Ser. No. 61/548,147 filed on Oct. 17, 2011, the contents of which are incorporated by reference herein in their entirety.

### FIELD OF INVENTION

The present invention relates to a mounting system for a photovoltaic module and more specifically, a mounting system that provides adjustability in order to facilitate mounting.

### SUMMARY

The present invention provides a photovoltaic (“PV”) module mounting system including a standoff adapted to be secured to a support surface, the standoff having an elongate channel extending along a length thereof. A rail attachment member has a portion disposed in the channel. The rail attachment member is positionably adjustable along the length of the rail. An elongate rail is securable to the standoff by the rail attachment member. The position of the rail is adjustable along the length of the standoff and fixedly secured. The elongate rail has a slot extending along a length thereof. The slot accommodates PV panel mounting hardware therein for securing a PV panel to the rail.

The present invention further provides a photovoltaic (“PV”) module mounting system including a standoff adapted to be secured to a support surface. The standoff has an elongate channel formed along a length thereof. An attachment block has a guide member disposed in the standoff channel. The attachment block is positionably adjustable along the length of the standoff. An elongate rail is fixedly securable to the attachment block. The position of the rail is adjustable along the length of the standoff The rail has a slot extending along a length thereof, and the slot accommodates PV panel mounting hardware therein for securing a PV panel to the rail.

The present invention still further provides a photovoltaic (“PV”) module mounting system including a first and a second elongate rail extending in a longitudinal direction and spaced from each other in a transverse direction. The transverse direction is generally perpendicular to the longitudinal direction. The rails are supported along their length by a plurality of standoffs. The standoffs include a positionally adjustable rail mounting member for permitting the position of the rails to be adjusted relative to each other in the transverse direction. At least one PV panel extends between the first and second rails and being secured thereto.

### BRIEF DESCRIPTION OF THE DRAWINGS

FIG. 1 is a top plan view of a PV panel mounting system of the present invention.

FIG. 2 is a top plan view of a PV panel mounting system of FIG. 1 prior to installation of one of the rails.

FIG. 3 is a side elevational view of PV panel attached to a rail and a standoff.

FIG. 4 is a perspective view of a standoff of the present invention.

FIG. 5 is a top plan view of a standoff mounted to a support surface.

FIG. 6 is an exploded perspective view of the standoff of FIG. 5.

FIG. 7 is a perspective view of the standoff of FIG. 5 secured to the support surface.

FIG. 8 is a perspective view of an alternative embodiment of a standoff.

FIG. 9 is a perspective view of an alternative embodiment of the present invention showing an attachment block disposed between a rail and a standoff.

FIG. 10 is a top perspective view of the embodiment of FIG. 9 prior to attachment of the rail to the attachment block.

FIG. 11 is an exploded top perspective view of the embodiment of FIG. 9.

FIG. 11A is a front elevational view showing two shims nested together.

FIG. 12 is an exploded bottom perspective view of the embodiment of FIG. 9.

FIG. 13 is a top perspective view of the embodiment of FIG. 9 showing the standoff secured to flashing.

FIG. 14 is an exploded view of the panel mounting system.

### DETAILED DESCRIPTION OF THE PREFERRED EMBODIMENTS

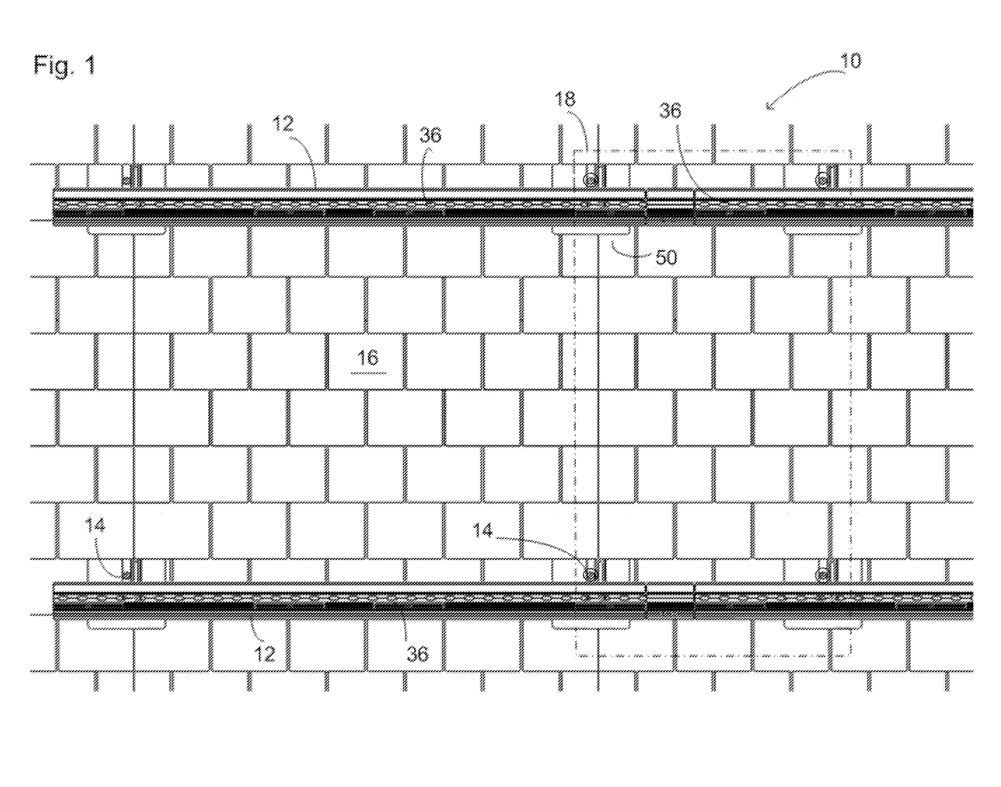

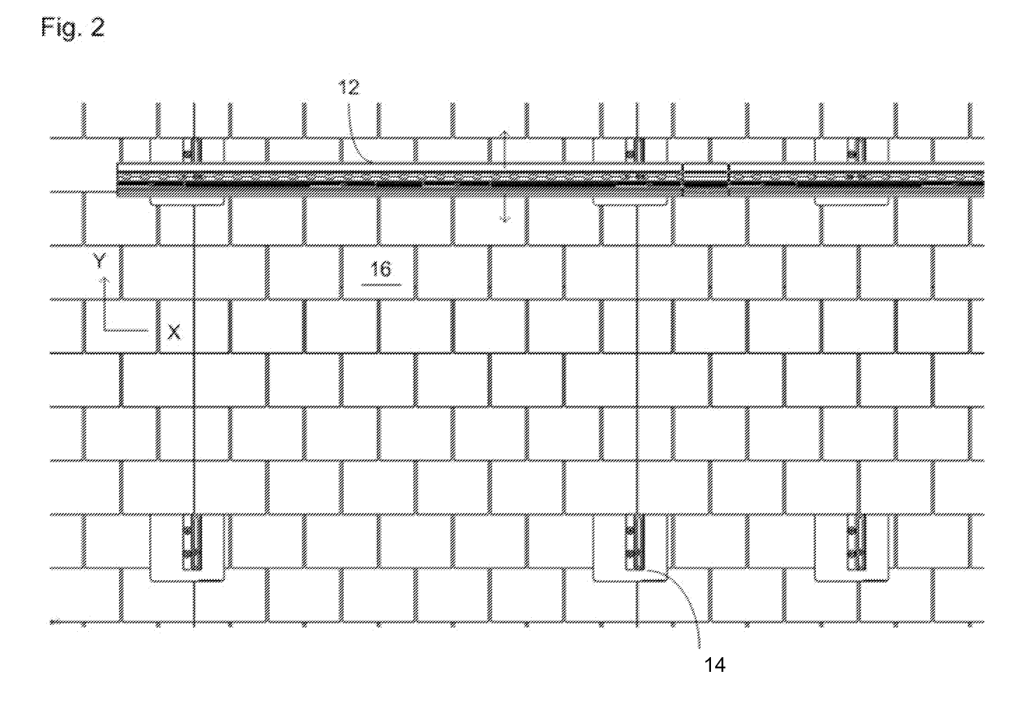

With reference to FIGS. 1-3, the photovoltaic (“PV”) module mounting system 10 includes a pair of spaced elongate mounting rails 12 which are supported along their length by a plurality of mounting standoffs 14. The mounting standoffs 14 space the rails 12 above a mounting surface 16 to which the standoffs are attached. The mounting surface may include the roof of a house, building or other structure. The mounting rails 12 are spaced from each other and aligned in a generally parallel orientation. The mounting rails 12 support thereon PV modules 18, each module including a solar panel and associated electrical components in order to permit the panel to be electrically connected to other PV modules and an electrical system.

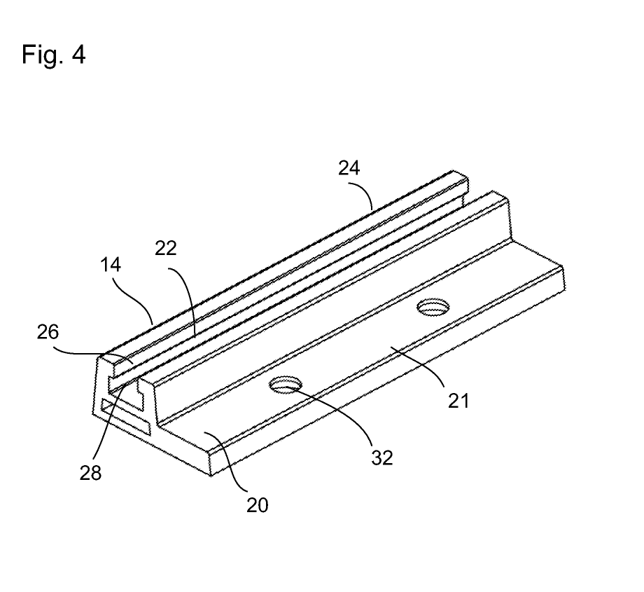

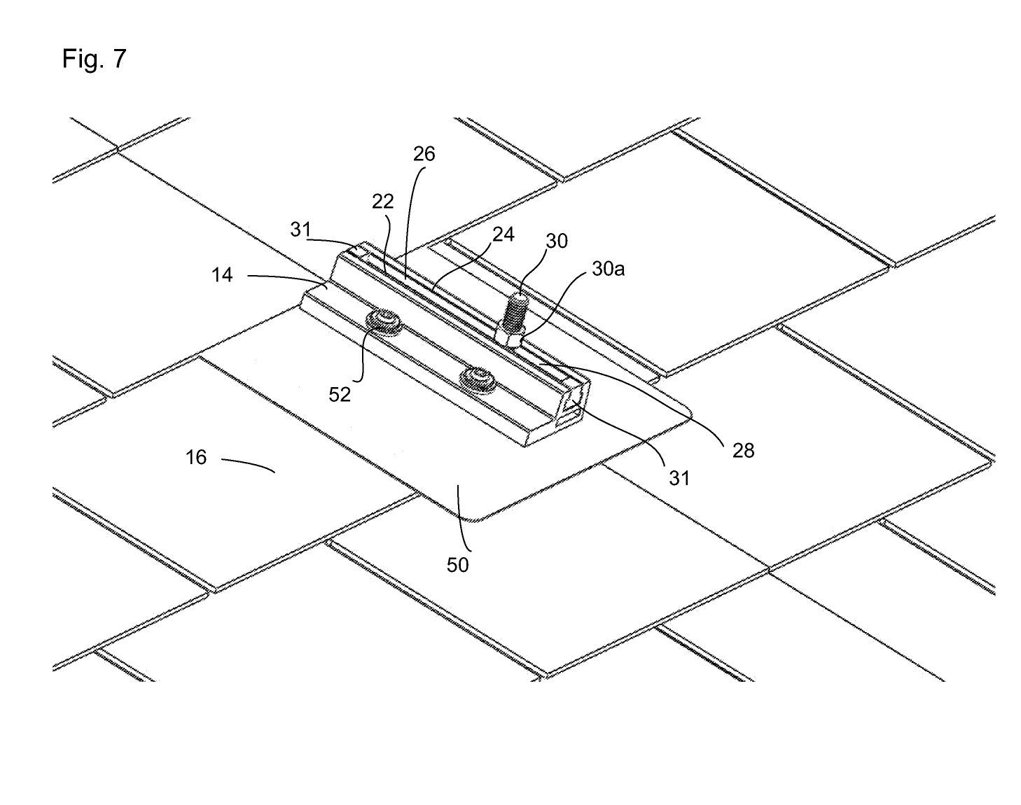

With additional reference to FIGS. 4-8, the standoffs 14 are generally elongate members having a base 20 supporting a slotted channel 22 extending along the length of the base. The standoffs 14 may be formed of a metallic material and may be formed by an extrusion process. The slotted channel 22 may have a generally inverted T-shaped configuration wherein a top portion 24 of the channel 22 extends inwardly to narrow a channel mouth 26. Accordingly, the channel interior 28 is wider than the channel mouth 26. This shape allows the head of a mounting rail fastener 30 to be slid within the channel 22 and captured therein. In order to retain the rail fastener 30 within the channel 22 prior to installation of the mounting rails, resilient plugs 31 may be inserted into the ends of the channel. The plugs 31 may be slid in the channel by a force exerted by the installer. An installer may move the fastener 30 in the channel 22 to a desired location and then slide the plugs against each side of the fastener such that the fastener is temporality held in place for installation.

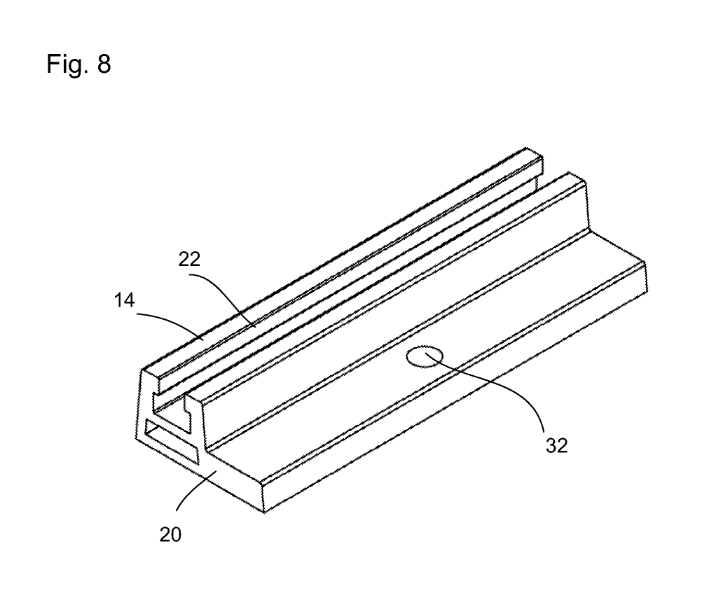

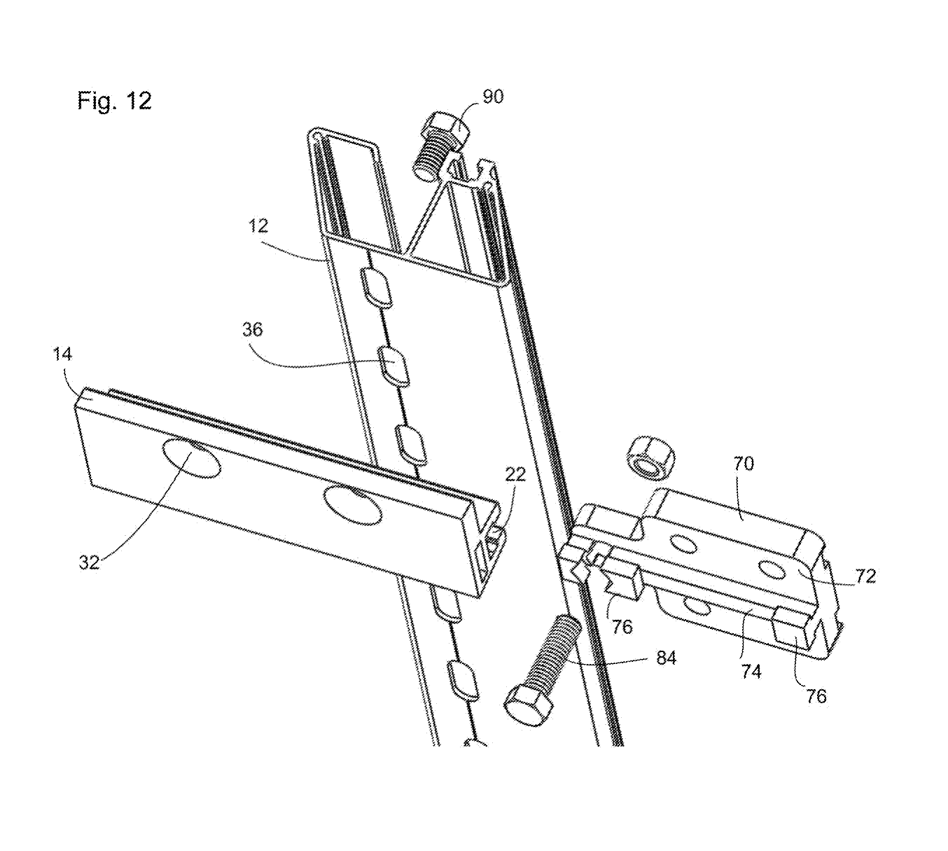

The base 20 may further include a generally planar portion 21 extending outwardly from the channel 22, which includes a one or more mounting openings 32. These openings permit the passage of roof fasteners 34 to extend there through in order to fixedly secure the mounting standoff 14 to the mounting surface 16. The mounting openings 32 may have a variety of configurations. For example, the standoffs 14 may include a single mounting opening or a plurality of mounting openings (FIG. 8). In addition, the mounting openings may be straight through holes or alternatively may be tapered or countersunk on the bottom (see FIG. 12) to hold an elastomeric washer.

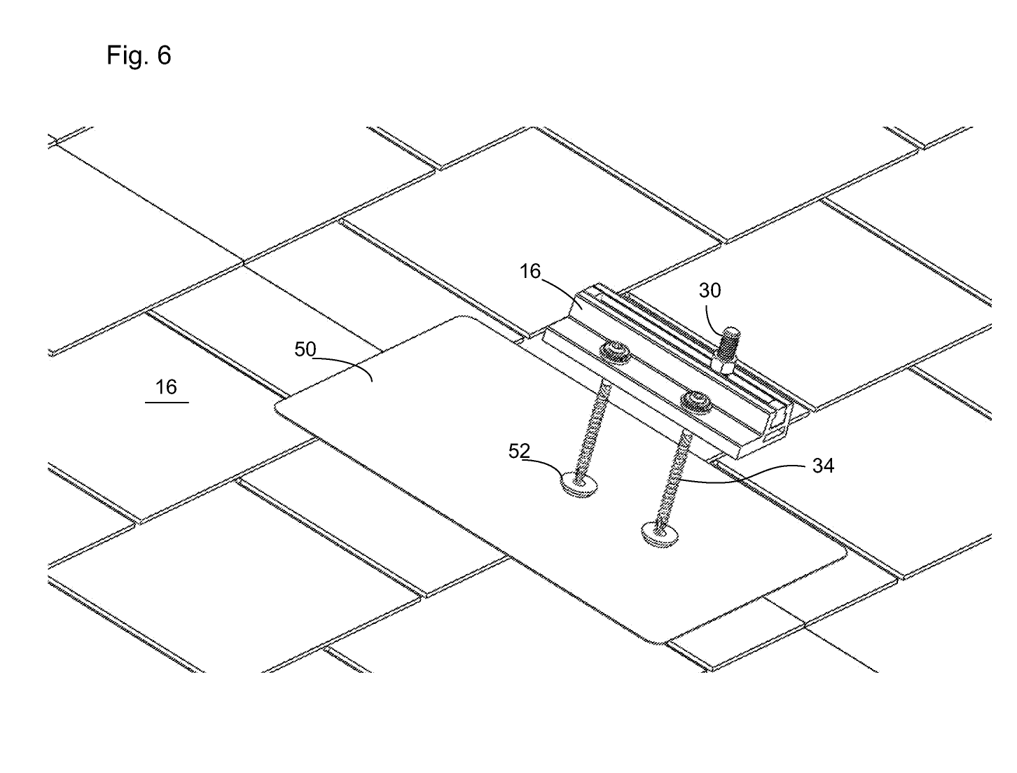

With reference to FIG. 6, the roof fasteners 34 extend into the support structure to secure the standoffs. In order to prevent leaking, the standoffs 14 may be disposed on a piece of flashing 50 and elastomeric washers 52 may be applied to the roof fasteners 34 such that the holes created by securing the standoffs to the roof are sealed against the elements. In an alterative embodiment, the flashing 50 may be integrally formed with, or connected to, the standoff. In this embodiment, the flashing may be secured to the bottom of the standoff by welding, riveting orbital riveting, adhesive or other connecting devices and methods known in the art.

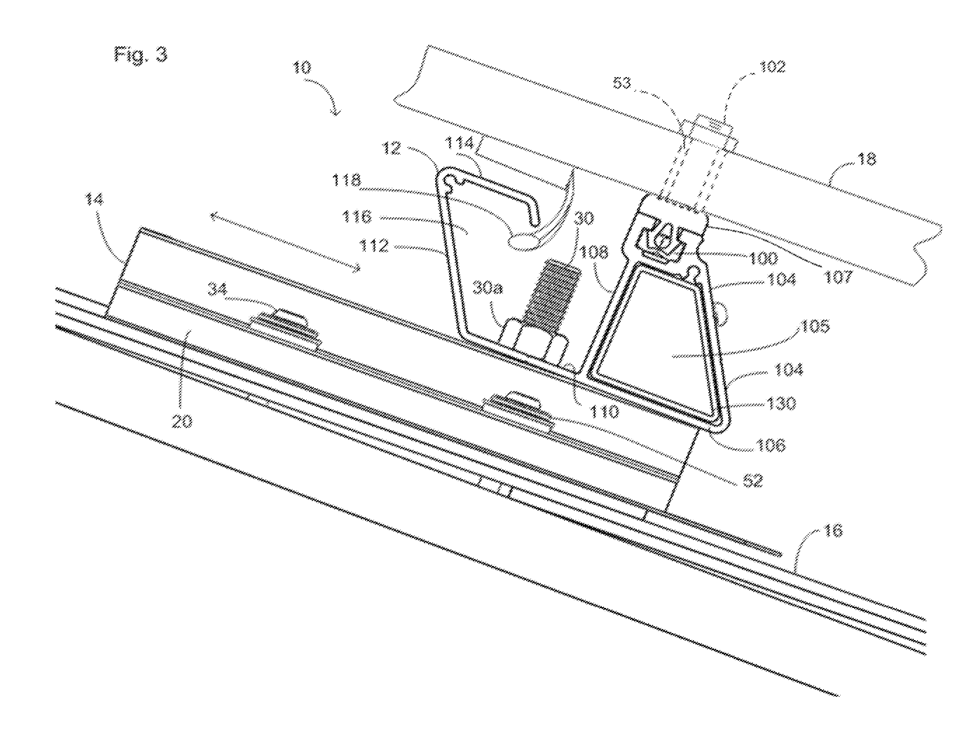

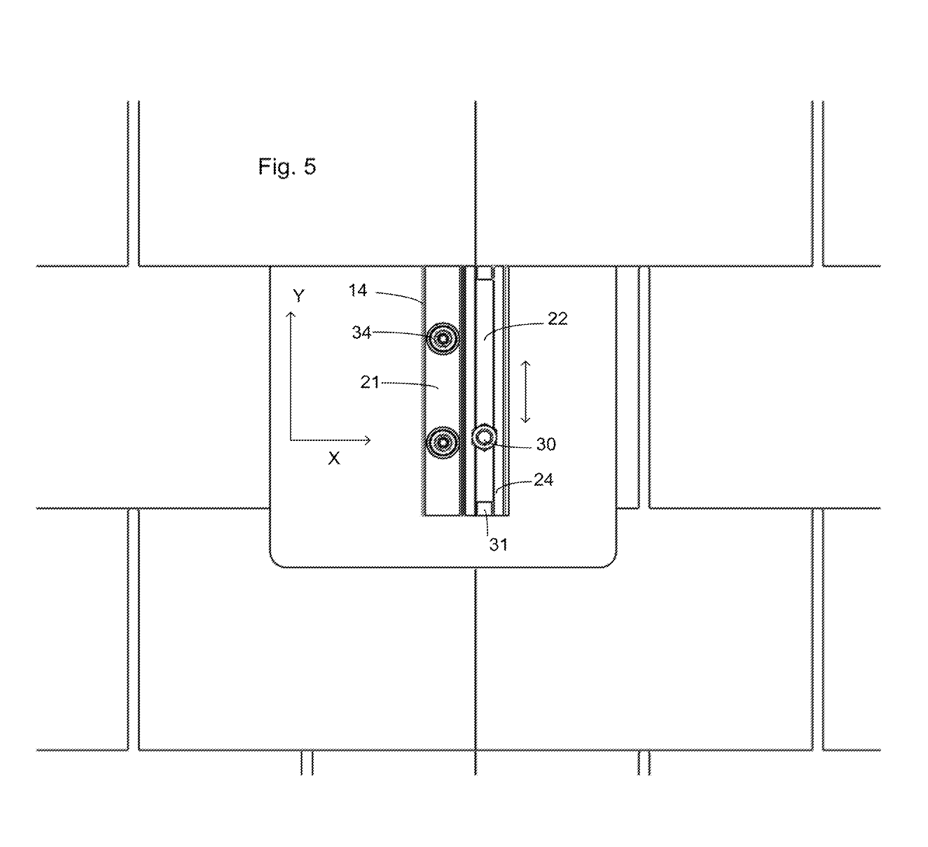

With reference to FIGS. 3 and 5, when securing the rails 12 to the standoffs, the rails need to align with fasteners 30 in the standoffs 14. In order to aid in this alignment, the mounting standoffs 14 are preferably disposed on the mounting surface 16 perpendicular to the longitudinal extent of the rails 12. The rail fasteners 30 may therefore, be positionally adjusted in the Y direction shown in FIG. 5. The mounting rails would be longitudinally aligned in the X direction. The rails 12 may include a series of attachment holes 36 in order to allow the rail fastener 30 contained within the standoff channel 22 to extend into and attach to the rail 12. Prior to tightening down the rail fasteners 30, the rails may be slid in the Y direction relative to the standoffs 14. Once the proper positioning of a rail is determined, the rail fastener 30 may be tightened, for example by tightening a nut 30a, thereby locking the position of the rail with respect to the standoff 14. This provides a degree of adjustability in a transverse direction Y perpendicular to the longitudinal extent of the mounting rails such that the desired spacing between the mounting rails 12 may be obtained so that the PV modules 18 may be properly installed on the rails 12.

The PV panels of the modules 18 may have mounting holes 53 formed therein and the mounting holes need to align with a mounting portion of the rails. Such adjustability of the rails is desirable so that the rails may be properly positioned to accept the PV modules. The mounting holes 53 may be spaced inwardly from side edges of the PV panels.

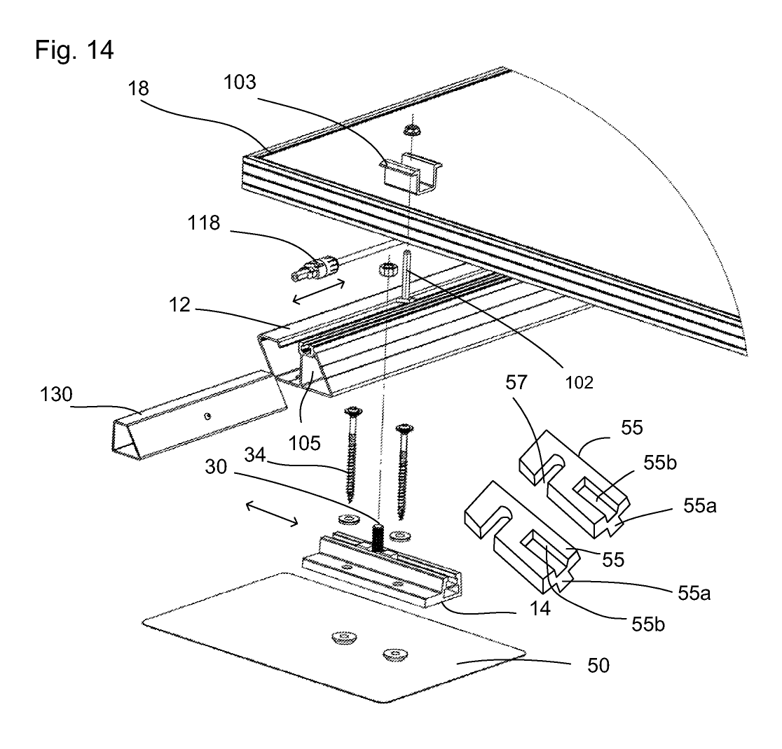

With reference to FIG. 14, shims 55 may be inserted between the top of the standoff and the bottom of the rail 12. Use of shims 55 may be desired in order to fill in any space between the top of the standoff and the bottom of the mounting rail that may exist due to irregularities in the roof. Shims 55 may include a slot 57 for receiving a rail fastener 30. The slot 57 allows the shims 55 to be added or removed when the rail is on the standoff. Shims may have a protrusion 55a extending form a bottom surface and a recess 55b formed in a top surface. The shims are nestable with each other with the protrusion 55a of an upper shim resting with in the recess 55b of the lower shim. For the shim that rest directly on top of the standoff 14, the protrusion 55a extends within the channel mouth 26. Due the interaction between the protrusion 55a and the channel mount 26 of the first shim, and the interaction of the protrusions 55a and recesses 55b of shims stacked on each other, the shims 55 will not rotate when the rail fastener 30 is tightened upon securing the rails to the standoff 14.

When securing the rails to a roof or other mounting surface 16, it is possible that due to the desired position of the rail 12, that the standoffs 14 may extend over the front edge of a roof shingle and onto the end of another shingle. In this case the mounting base of the standoff would be uneven. This problem is especially pronounced when the desired standoff position is located at the transition between one course of shingles and another. Accordingly, in the past, an installer would be required to notch the shingles so that the standoffs 14 would be supported against only one shingle. The standoff 14 of the present invention with its positionally adjustable rail fastener overcomes this problem of the prior art by allowing the standoffs to be secured to one course of shingles. In addition, the standoff 14 may be secured on top of one shingle and cantilevered over the lower course of shingles as shown in FIG. 5. Therefore, a rail fastener 30 may be positioned over the shingle course transition. Since the significant portion of the standoff 14 would be supported by the one shingle course, a stable mounting position is obtained.

Accordingly, a rail 12 may be positioned and secured over the transition between one course of shingles and another by using the standoff of the present invention, without the need for modifying the shingles.

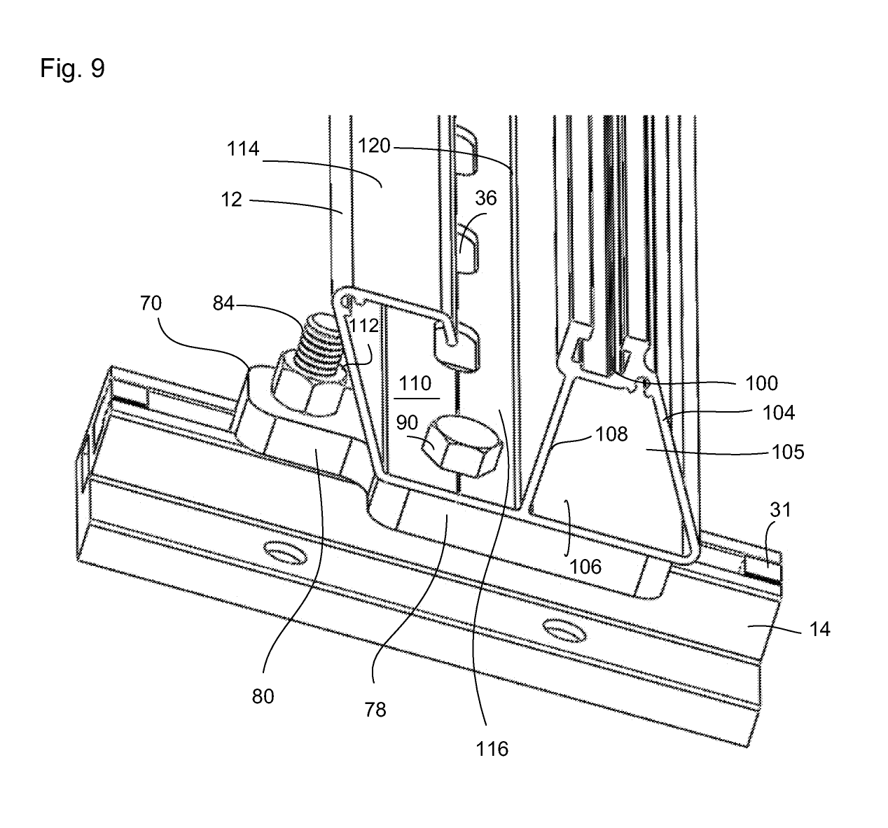

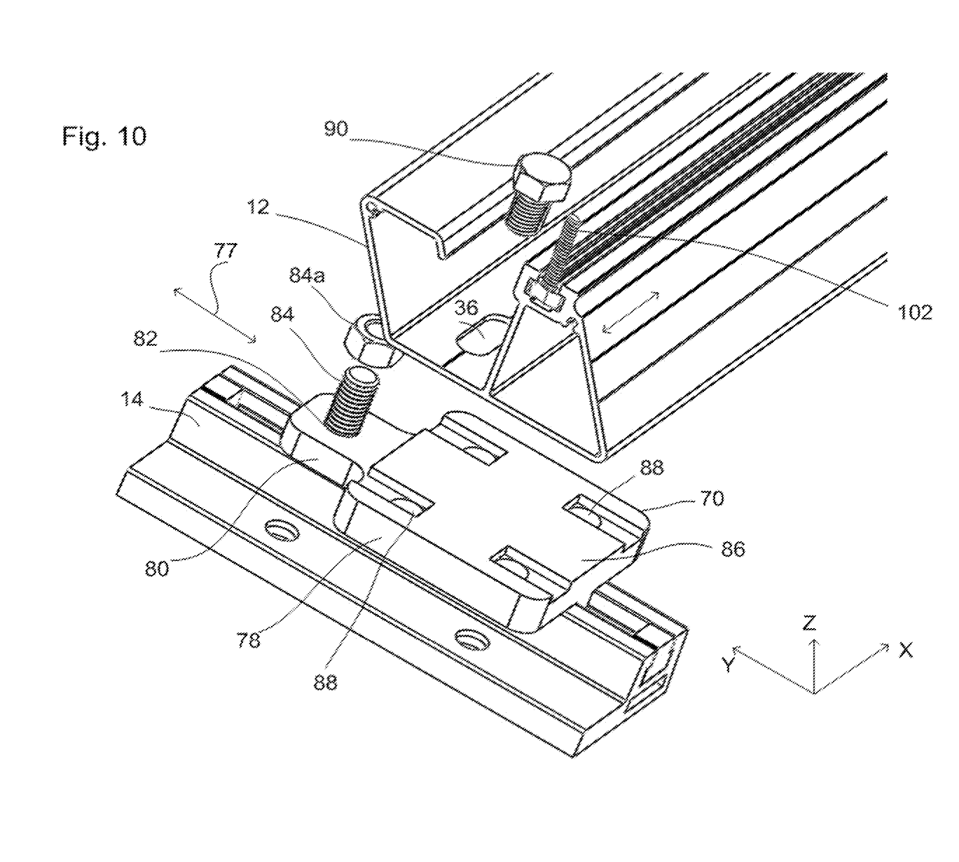

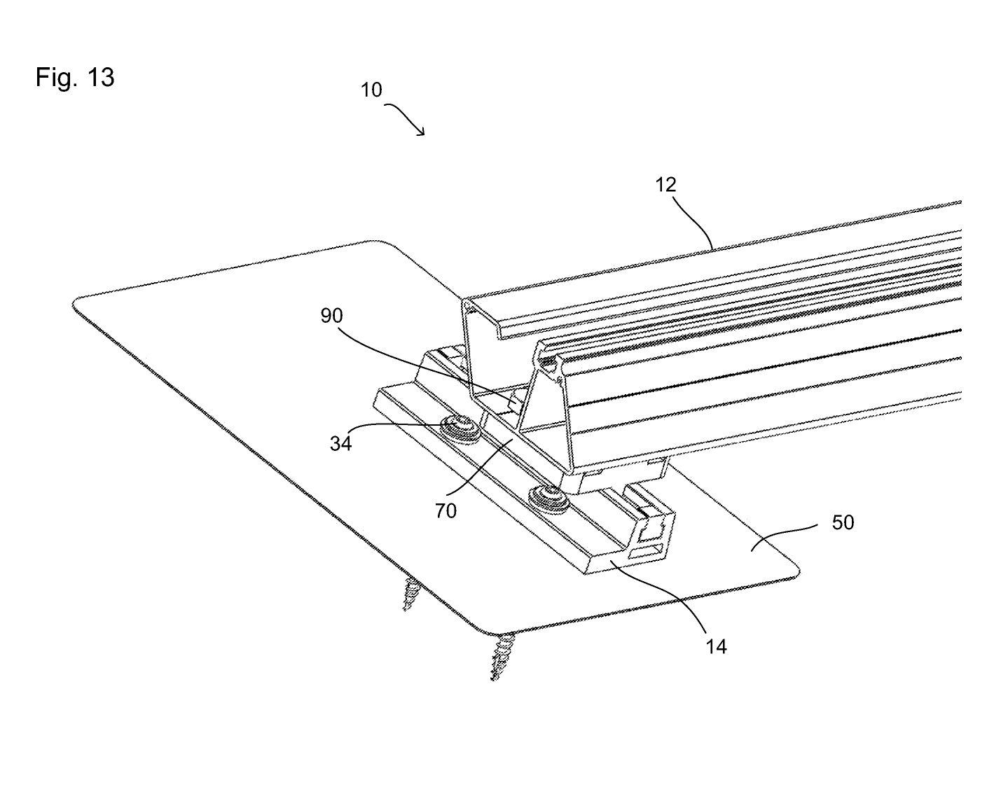

In an alternative embodiment shown in FIGS. 9-13, an attachment block 70 may be disposed between the standoff 14 and the rail 12, and the rails 12 are attached and secured to the attachment blocks 70. The use of attachment blocks 70 provides greater flexibility in mounting applications as discussed below. The attachment block 70 may include a bottom side 72 having a longitudinally extending protrusion 74. Spaced on the protrusion are inverted T-shaped guide members 76 which slide within the standoff channel 22. Accordingly, the attachment block 70 may be slid along the length of the standoff in a guided manner as shown by arrow 77 in FIG. 10. However, due to the cooperation between the channel 22 and the guide members 76, the attachment block 70 cannot be separated from the standoff 14 in a direction Z (FIG. 10) generally perpendicular to the length of the channel 22. The attachment block 70 may include a main body 78 and a longitudinally extending head portion 80 extending therefrom. The head portion 80 includes an opening 82 for receiving a mounting block fastener 84. The attachment block 70 may be slid to a desired position along the length of the standoff 14 and then secured in place by tightening a nut 84a of the mounting block fastener 84. Since the attachment block 70 can be positionally fixed with respect to the standoff 14 before placing on the rail, no further adjustment is required when mounting the rails 12. This helps to simplify the installation.

An attachment block upper surface 86 forms a support upon which the bottom of the rail 12 may rest. The upper surface 86 may include a plurality of spaced mounting holes 88 that are adapted to receive rail mounting hardware 90 which may be in the form of a threaded bolt. The mounting holes 88 are spaced from each other in both the longitudinal direction of the rail X and in the longitudinal direction of the standoff Y. Since there is a plurality of spaced mounting holes 88, if one hole lies in between the rail attachment holes 36, the other mounting hole 88 will be available to fasten the mounting rail 12. Having multiple spaced mounting holes 88 eliminates the need to drill another hole in the rail 12 on site when the mounting holes 88 and rail attachment holes 36 do not align.

The attachment block 70 can be installed in one of two orientations with respect to the standoff 14. This can be achieved by rotating the attachment block 180 degrees with respect to the standoff 14. In this way, the mounting holes 88 may be located virtually anywhere along the length of the attachment block 70.

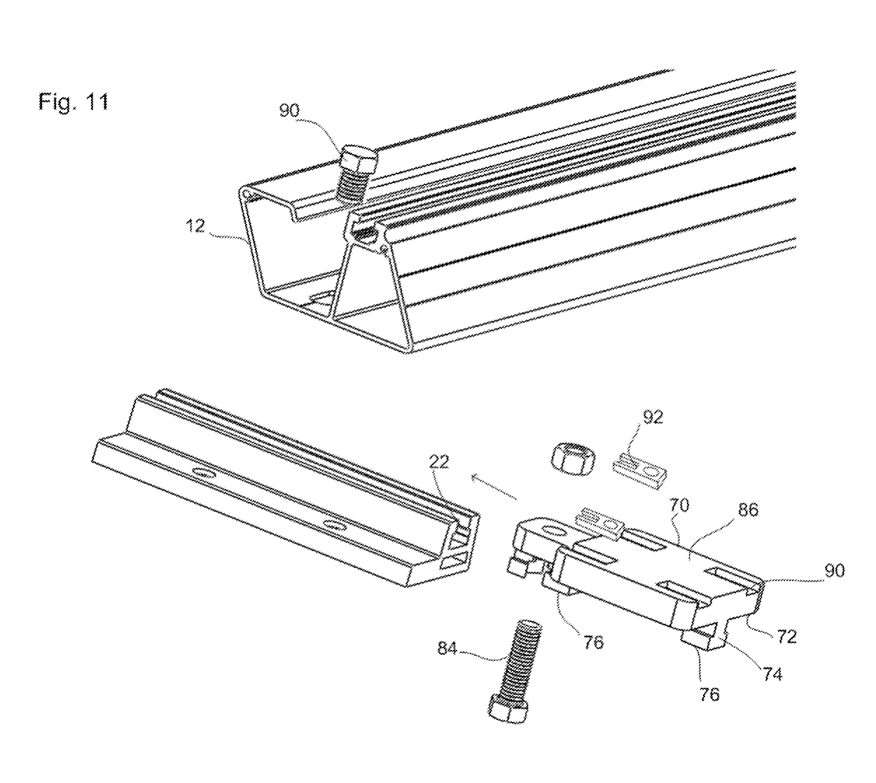

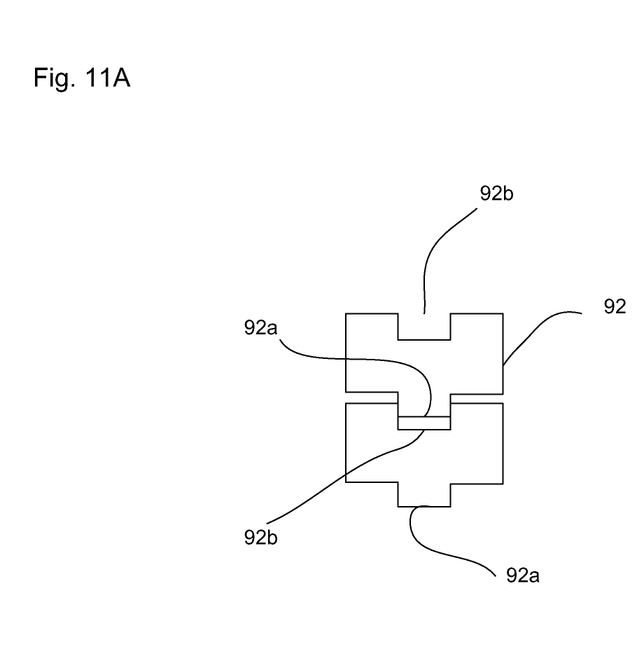

With reference to FIG. 11, adjacent each of the attachment block mounting holes 88 is a slot 90, which is adapted to receive a shim 92. Use of a shim 92 may be necessary in order to fill in any space between the attachment block upper surface 86 and the bottom of the mounting rail. Such spaces may occur due to irregularities in the roof.

It is within the contemplation of the present invention that a plurality of shims could be placed in the slots with one stacked upon the other in order to fill the space. The shims 92 would be kept in place by attaching the rail 12 to the attachment block 70. With additional reference to FIG. 11A, in a manner similar to the shims 55 described above, the shims 92 may nest within each other. Each shim 92 having a projection 92b extending from a bottom surface and a recess 92b formed in a top surface. When the shims 92 are stacked on each other, the projection 92 of the upper shim will sit within the recess 92b of the adjacent lower shim 92.

The attachment blocks 70 may be formed of a metallic material such as steel or aluminum and the mounting holes therein may be threaded to receive the rail mounting hardware 90. Alternatively, the attachment block 70 may be formed of a polymer or a composite material.

With reference to FIGS. 3, 9, 10 and 14, the elongate rails 12 to which the PV modules 18 are attached may have a cross-sectional profile including an elongate mounting slot 100 formed therein. The mounting slot 100 may be used to capture the head of a fastener 102 such that a fastener may be slid along the length of the mounting channel 100 to a desired mounting position. The fastener 102 may then extend through a hole in the PV module 53 (FIG. 3) or it may be attached to a clip 103 (FIG. 14) which engages the side of the module and secures it to the rail 12. An insulating rubber strip 107 may be inserted into the mounting slot 100 upon which the back of the PV module 18 would rest.

Due to the ability to positionally adjust the fastener 102 in the mounting slot 100, the PV modules may be secured to the rails at various locations along the length of the rails. With this ability to adjust the fastener 102 in the X direction, and the ability to adjust the mounting position of the rail with respect to the standoffs in the Y direction, installation of the PV modules is simplified.

The mounting slot 100 is supported by a support structure 104 which may include a first sidewall 104, a base wall 106 extending generally perpendicular therefrom, and an opposed second sidewall 108 extending from the base wall 106 to the slot 100. The walls of the support structure 104 form an enclosed channel 105 having a generally frusto-triangular cross-section configuration.

Extending from the support structure base 106 is a mounting wall 110 which may include a plurality of mounting holes 112. The holes accommodated rail mounting hardware 90 for securing the rail to the attachment block 70 or can accommodate the rail fastener 30 in the case where an attachment block 70 is not used. In an alternative embodiment, the mounting wall 110 may not include any preformed mounting holes, and the desired mounting hole would be formed therein by an installer.

Extending at a generally obtuse angle from the mounting wall 110 is an upwardly extending wall 112 which at its upper end is connected to a top wall 114 that extends partway toward the support structure 104. Walls 110, 112 and 114 form a wireway 116. Wireway 116 is generally an open channel which allows wiring 118 from the PV modules to be run therein. The channel has an open top 120 which is generally covered when the PV module 18 is attached to the rails 12.

Rails 12 may be secured together end to end by using a splice 130 which extends into the support structure channels 105 of the abutted elongate rails 12. The splice 130 may have a configuration generally similar to the support structure channel 105 so that it fits therein in a generally close relationship.

While the above described mounting system 10 has shown the standoffs 14 secured to rail 12, it is within the contemplation of the present invention that the standoffs 14, either with or without the attachment blocks 70, may be used to secure on a support surface various types of rails, brackets, connectors, and other mounting and securement hardware.

It will be appreciated that various embodiments of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

What is claimed is:

1. A photovoltaic (“PV”) module mounting system comprising:
a standoff adapted to be secured to a support surface, the standoff having an channel extending along a length thereof;
a rail attachment member having a portion disposed in the channel, the rail attachment member being positionably adjustable along the length of the rail; and
an elongate rail securable to the standoff by the rail attachment member, the position of the rail being adjustable along the length of the standoff and fixedly secured thereto, the elongate rail having a slot extending along a length thereof, the slot accommodating PV panel mounting hardware therein for securing a PV panel to the rail.

2. The mounting system as defined in claim 1, wherein a longitudinal extent of the standoff channel is generally perpendicular to a longitudinal extent of the rail slot.

3. The mounting system as defined in claim 1, wherein the PV panel mounting hardware is positionally adjustable along the length of the rail such that PV modules may be secured to the rail at any position along the length of the rail.

4. The mounting system as defined in claim 1, wherein the rail attachment member includes a bolt having a head disposed within the channel, the bolt extending through a hole in the rail, a nut threadedly engagable with the bolt for fixably securing the rail to the standoff.

5. The mounting system as defined in claim 1, wherein the rail attachment member includes a mounting block adjustably positionable in the standoff channel and fixedly securable therein.

6. The mounting system as defined in claim 5, wherein the mounting block includes at least one mounting hole therein for receiving mounting hardware, the mounting hardware securing the rail to the attachment block.

7. The mounting system as defined in claim 6, a first shim disposed between the standoff and the elongate rail for accommodating a space therebetween.

8. The mounting system as defined in claim 7, further including a second shim, the second shim being nestable with the first shim.

9. The mounting system as defined in claim 8, wherein the first shim has a recess on an upper surface, the second shim having a protrusion extending from a lower surface thereof, the second shim protrusion resting within the first shim recess.

10. A photovoltaic (“PV”) module mounting system comprising:
a standoff adapted to be secured to a support surface, the standoff having an elongate channel formed along a length thereof;
an attachment block having a guide member disposed in the standoff channel, the attachment block being positionably adjustable along the length of the standoff; and
an elongate rail fixedly securable to the attachment block, the position of the rail being adjustable along the length of the standoff, the rail having a slot extending along a length thereof, the slot accommodating PV panel mounting hardware therein for securing a PV panel to the rail.

11. The mounting system as defined in claim 10, wherein the mounting block has a plurality of mounting holes formed therein for accommodating mounting hardware for securing the elongate rail to the mounting block.

12. The mounting system as defined in claim 10, wherein the guide member is engagable with the standoff wherein the mounting block is slidable along a length of the standoff channel but the standoff is not movable out of the channel in a direction perpendicular to the length of the channel.

13. The mounting system as defined in claim 10, wherein the guide member includes a pair of spaced guides slidable within the channel.

14. The mounting system as defined in claim 10, wherein the mounting block includes a generally planar mating surface engagable with the elongate rail, the mating surface including a depression therein for accommodating a first shim, the first shim extending above the mounting block mating surface for accommodating a space between the mounting block and the elongate rail.

15. The mounting system as defined in claim 14, further including a second shim, the second shim being nestable with the first shim.

16. The mounting system as defined in claim 15, wherein the first shim has a recess on an upper surface, the second shim having a protrusion extending from a lower surface thereof, the second shim protrusion resting within the first shim recess.

17. A photovoltaic (“PV”) module mounting system comprising:
a first and a second elongate rail extending in a longitudinal direction and spaced from each other in a transverse direction, the transverse direction being generally perpendicular to the longitudinal direction, the rails being supported along their length by a plurality of standoffs, the standoffs including a positionally adjustable rail mounting member for permitting the position of the rails to be adjusted relative to each other in the transverse direction; and
at least one PV panel extending between the first and second rails and being secured thereto.

18. The mounting system as defined in claim 17, wherein the standoffs each include a channel extending along a length thereof, and the rail mounting member is adjustably positionable along the length of the slot wherein the transverse distance between the first and second rails is adjustable.

19. The mounting system as defined in claim 18, wherein the rail attachment member includes a mounting block adjustably positionable in the standoff channel and fixedly securable therein, and the mounting block includes at least one mounting hole therein for receiving mounting hardware, the mounting hardware fixedly securing the rail to the attachment block.

20. The mounting system as defined in claim 18, wherein the mounting block includes a plurality of spaced mounting holes wherein the rail is securable to at least one of the mounting holes.

21. The mounting system as defined in claim 18, wherein the first and second rails each include a slot extending along a length thereof, the at least one PV panel being adjustably secured to the first and second rails at a position along the slot, wherein the position of the PV panel is adjustable on the first and second rails along the longitudinal direction.
